(19) United States
(12) Patent Application Publication
(10) Pub. No.: US 2026/0349047 A1
(43) Pub. Date: Nov. 5, 2026

(54) BATTERY SERVICING SYSTEM AND BATTERY SERVICING METHOD

(71) Applicant: AUTOCRAFT SOLUTIONS GROUP LIMITED, Belton (GB)

(72) Inventors: Dan Nickerson, Belton (GB); Simon Warburton, Belton (GB)

(73) Assignee: AUTOCRAFT SOLUTIONS GROUP LIMITED, Belton, KC (GB)

(21) Appl. No.: 18/997,458

(22) PCT Filed: Jul. 20, 2023
(86) PCT No.: PCT/GB2023/051906

§ 371 Date: Jan. 21, 2025

(30) Foreign Application Priority Data
Jul. 22, 2022 (GB) 2210746.0

(51) Int. Cl. G01R 31/396; B60L 53/80; B60L 58/16; G01R 31/36; G01R 31/385; H01M 10/04; H01M 10/42

(52) U.S. Cl. CPC G01R 31/396; G01R 31/3644; G01R 31/385; H01M 10/0404; H01M 10/4285; B60L 53/80; B60L 58/16; B60L 2240/547; B60L 2240/549

(57) ABSTRACT

A battery servicing system that includes a plurality of actuators and a controller, which causes the plurality of actuators to connect a fluid line and an electrical line to a battery pack placed in a battery servicing station. The controller is further configured to perform one or more tests on the battery pack to identify an anomaly or an adverse event in one or more cells in the battery pack. The controller is further configured to control the plurality of actuators to automatically disconnect the fluid line and the electrical line from the battery pack being tested to eject the battery pack from the battery servicing station when the anomaly or an adverse event is identified. The battery servicing system allows a safe disconnection and ejection of the battery pack.

### TECHNICAL FIELD

The present disclosure relates generally to the field of electric vehicles and battery servicing systems, and more specifically, to a battery servicing system and a battery servicing method for safe disconnection of power and fluids for electric vehicle battery testing.

### BACKGROUND

Generally, an electric vehicle service station is used for manufacturing, testing, and processing batteries that are used in electric vehicles, hybrid electric vehicles, plug-in hybrid electric vehicles, and the like. However, the testing is usually limited to prototype testing or testing of newly manufactured batteries or to develop new batteries. In certain scenarios, for example, after prolonged use, some batteries may develop some defects and may not function properly. Such defective batteries are currently required to be transported to a dealer or a service station, where they are usually discarded. Transportation and handling of such defective batteries is a huge industry-wide problem as they are classified as dangerous goods.

Currently, certain attempts have been made in order to transport the defective EV batteries, for example, by use of forklifting or other known lifting methods (that are again human assisted). However, existing lifting methods involve a potentially hazardous movement of the defective EV batteries as it requires human intervention and dropping a large and heavy EV battery at a safe location. Thus, there exists a technical problem of how to develop a holistic testing process that is valid for not only developing new EV batteries but also effective for used EV batteries and further how to ensure safe transportation of the defective EV batteries that may be hazardous to human life.

Therefore, in light of the foregoing discussion, there exists a need to overcome the aforementioned drawbacks associated with the conventional methods of transporting the malfunctioned batteries.

### SUMMARY

The present disclosure provides a battery servicing system and a battery servicing method. The present disclosure provides a solution to the existing problem of how to develop a holistic testing process that is valid for not only developing new EV batteries but also effective for used EV batteries and further how to ensure a safe ejection of a malfunctioned battery. An aim of the present disclosure is to provide a solution that overcomes at least partially the problems encountered in the prior art and provide an improved battery servicing system and an improved battery servicing method for automatic and safe disconnection of power and fluids connections (or lines) for electric vehicle battery testing.

One or more objects of the present disclosure is achieved by the solutions provided in the enclosed independent claims. Advantageous implementations of the present disclosure are further defined in the dependent claims.

In one aspect, the present disclosure provides a battery servicing system that includes a plurality of actuators and a controller. The controller is configured to cause the plurality of actuators to connect a fluid line and an electrical line to a battery pack placed in a battery servicing station. Further, the controller is configured to perform one or more tests on the battery pack to identify an anomaly in one or more cells in the battery pack. Further, control the plurality of actuators to automatically disconnect the fluid line and the electrical line from the battery pack being tested to eject the battery pack from the battery servicing station when an anomaly or an adverse event is identified. The term “anomaly” may be interpreted to include any anomaly, or an adverse event identified in the battery pack.

The battery servicing system is flexible and universal in use (i.e., suitable to perform tests on all types of EV batteries irrespective of their manufacturers or product type and even effective to perform tests on used EV batteries). The battery servicing system enables safe and automatic disconnection of the fluid line and the electrical line from the battery pack prior to the ejection of the battery pack. Due to the automatic ejection of the battery pack, no lifting equipment, and human intervention is required for transportation of the battery pack in which an anomaly or the adverse event is identified. As a result, the battery servicing system further reduces the risk of any damage to the battery servicing station as well as any harm to the life of operators working at the battery servicing station.

In an implementation form, the performing of the one or more tests to identify the anomaly includes measuring a defined set of battery parameters of the battery pack being tested. Further, comparing the measured defined set of battery parameters with a predefined set of reference parameters to find whether a deviation of one or more battery parameters is greater than a corresponding threshold value.

By virtue of comparing the measured defined set of battery parameters with a predefined set of reference parameters, the controller enables the battery servicing system to identify the health of the battery pack and further repair or replace components in the battery pack according to the health of the battery pack.

In a further implementation form, the defined set of battery parameters of the battery pack includes voltage and current parameters, direct current internal resistance, an amount of heat generated while being charged/discharged, a fluid leakage, a charge-discharge rate, and a status of health (SoH) parameters.

The defined set of battery parameters of the battery pack is used to determine whether the one or more cells of the battery pack can be replaced, reused, or may be recycled.

In a further implementation form, the battery servicing system further includes a link harness. Moreover, the fluid line and the electrical line are connected to the battery pack via the link harness.

In this implementation, the link harness enables the battery servicing system to provide a standard connection for the fixation of the battery pack. The link harness removes the difficulty of connecting different types of connectors to the battery servicing system.

In a further implementation form, the fluid line and the electrical line are automatically disconnected from the battery pack by a pulling action of the link harness caused by the controlling of the actuator.

In this implementation, the pulling action of the link harness is used to safely disconnect the battery pack from the battery servicing station.

In a further implementation form, the performing of the one or more tests further includes determining a severity level of damage to the battery pack.

The determination of the severity level of the damaged battery pack enables the battery servicing system to determine if the battery pack can be ejected or not.

In a further implementation form, determining the severity level of damage to the battery pack includes determining a number of cells that need to be replaced in the battery pack.

In this implementation, the determination of the number of cells that needs to be replaced in the battery pack enables the battery servicing system to improve the lifetime of the battery pack, such as by replacing the number of cells.

In a further implementation form, the battery pack is ejected from the battery servicing station when the severity level of the anomaly is greater than a defined threshold.

The ejection of the battery pack from the battery servicing station enables the battery servicing system to reduce the risk of any damage to the battery servicing station as well as any harm to the life of operators working at the battery servicing station.

In a further implementation form, the controller is further configured to generate simulation data indicative of an extent of restoration of the battery pack feasible by replacing the one or more cells that are identified with the anomaly.

The simulation data enables the battery servicing system to identify the one or more cells that are required to be replaced in the battery pack that is used to improve the ratio of cost and performance of the battery pack and to increase the lifespan of the battery pack.

In a further implementation form, the controller is further configured to execute a re-testing of the battery pack after the replacement of the one or more cells that are identified with the anomaly. The controller is further configured to re-generate simulation data indicative of the extent of restoration achieved and a status of health of the battery pack after replacement of the one or more cells that are identified with the anomaly.

Beneficially, the re-testing of the battery pack after the replacement of the one or more cells enables the battery servicing station to determine the safe and efficient replacement of the one or more cells of the battery pack.

In a further implementation form, the controller is further configured to control one or more actuators of the plurality of actuators to position the battery pack on a lid that is configured as a test plate on a workstation during the one or more tests of the battery pack. Moreover, the ejection of the battery pack includes dropping a container part on to the battery pack to contain the battery pack.

In this implementation, controlling the one or more actuators of plurality of the actuators to position the battery pack on the lid of the isolation unit enables the battery servicing system to perform an efficient and accurate ejection of the battery pack.

In a further implementation form, the battery servicing system further includes an off-grid energy storage system and operations of the battery servicing system are powered by the off-grid energy storage system.

In this implementation, the off-grid energy storage system is beneficial for providing an off-grid power supply to the battery servicing system and enables the battery servicing system to operate during grid power failure too.

In a further implementation form, the battery servicing station is an off-grid mobile electric vehicle battery servicing station.

In this implementation, the off-grid mobile electric vehicle battery servicing station provides a portable solution that enables easy battery servicing for testing of the battery pack.

In another aspect, the present disclosure provides a method for servicing a battery pack. The battery pack further includes causing a plurality of actuators to connect a fluid line and an electrical line to a battery pack placed in a battery servicing station. Furthermore, performing one or more tests on the battery pack to identify an anomaly in one or more cells in the battery pack. Furthermore, controlling the plurality of actuators to automatically disconnect the fluid line and the electrical line from the battery pack being tested to eject the battery pack from the battery servicing station if a malfunction is identified that represents a risk to human or equipment safety.

The method for servicing the battery pack achieves all the advantages and effects of the battery servicing system.

It is to be appreciated that all the aforementioned implementation forms can be combined.

It has to be noted that all devices, elements, circuitry, units and means described in the present application could be implemented in the software or hardware elements or any kind of combination thereof. All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof. It will be appreciated that features of the present disclosure are susceptible to being combined in various combinations without departing from the scope of the present disclosure as defined by the appended claims.

Additional aspects, advantages, features and objects of the present disclosure would be made apparent from the drawings and the detailed description of the illustrative implementations construed in conjunction with the appended claims that follow.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale. Wherever possible, like elements have been indicated by identical numbers.

Embodiments of the present disclosure will now be described, by way of example only, with reference to the following diagrams wherein:

FIG. 1A is a block diagram that illustrates a battery servicing station comprising a battery servicing system, in accordance with an embodiment of the present disclosure;

FIG. 1B is a block diagram that illustrates various exemplary components of a battery servicing system, in accordance with an embodiment of the present disclosure;

FIG. 2 is an exemplary illustration that represents a movement of a battery pack into a container part at a battery servicing station, in accordance with an embodiment of the present disclosure;

FIG. 3A is an exemplary illustration to perform one or more tests and identify an anomaly in one or more cells of a battery pack, in accordance with an embodiment of the present disclosure;

FIG. 3B is an exemplary illustration that represents an anomaly in a battery pack and a corresponding simulation data, in accordance with an embodiment of the present disclosure;

FIG. 3C is an exemplary illustration that represents a robotic arm to withdraw one more cells from a battery pack that is identified with an anomaly, in accordance with an embodiment of the present disclosure;

FIG. 3D is an exemplary illustration to perform re-testing of a battery pack, in accordance with an embodiment of the present disclosure;

FIG. 3E is an exemplary illustration for an arrangement of a workstation and a container part of a battery servicing system outside a battery servicing station, in accordance with an embodiment of the present disclosure; and

FIG. 4 is a flowchart of a method for servicing a battery pack, in accordance with an embodiment of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practising the present disclosure are also possible.

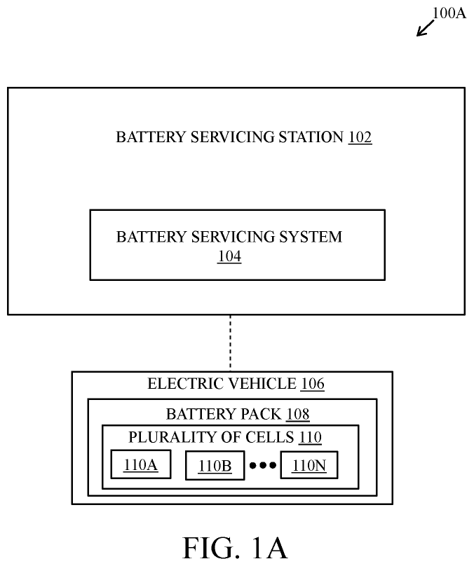

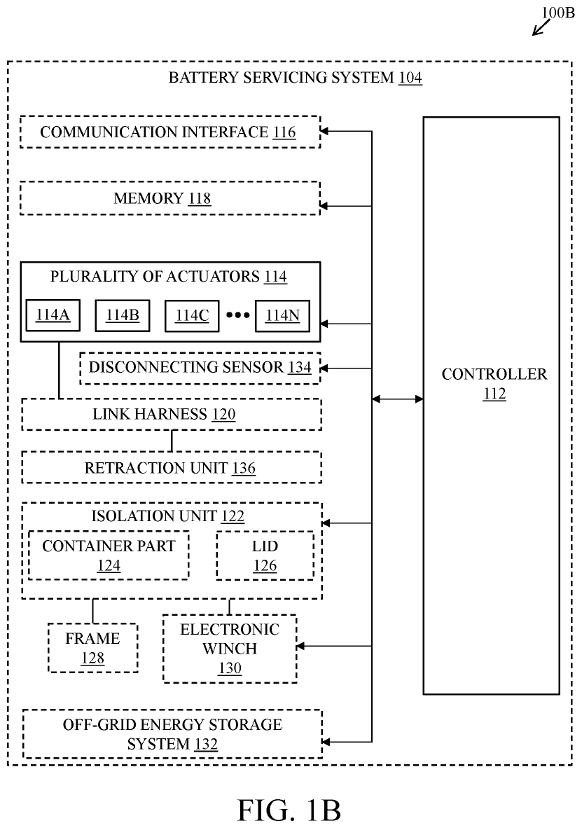

FIG. 1A is a block diagram for a battery servicing station comprising a battery servicing system, in accordance with an embodiment of the present disclosure. The diagram 100A shows a battery servicing station 102 comprising a battery servicing system 104. There is further shown an electric vehicle 106 comprising a battery pack 108. The battery pack 108 comprises a plurality of cells 110, such as a first cell 110A, a second cell 110B, and up to an Nth cell 110N.

The battery servicing station 102 may be used for manufacturing, processing, and testing electric vehicle (EV) batteries, such as the battery pack 108. In an implementation, the battery servicing station 102 may be a mobile electric vehicle battery servicing station, or an off-grid mobile electric vehicle battery servicing station. In another implementation, the battery servicing station 102 may be a station located at a fixed place.

The battery servicing system 104 is configured for use in the battery servicing station 102. The battery servicing system 104 is configured to identify an anomaly or an adverse event in one or more cells from the plurality of cells 110 of the battery pack 108. The battery servicing system 104 is also configured to perform automatic disconnection of power and fluids from the battery pack 108 prior to ejection of the battery pack 108 based on the anomaly or the adverse event in one or more cells of the battery pack 108.

The battery pack 108 corresponds to an energy storage device that is used in the electric vehicle 106. The battery pack 108 may include the plurality of cells 110, such as the first cell 110A, the second cell 110B, and up to the Nth cell 110N. In an example, the battery pack 108 includes one or more battery modules that further include one more battery cell. The term “servicing” includes picking an EV battery from an electric vehicle or another remote location, automatically performing battery triage operations (e.g., one or more tests and advanced diagnostics and characterization with a view to repair the EV battery), performing repair of the EV battery where possible, and automatically and safely ejecting and transporting the malfunctioned battery.

In an implementation, the electric vehicle 106 may arrive at the battery servicing station 102 for testing of the battery pack 108. Alternatively, the battery servicing station 102 may be mobile, for example, the battery servicing station 102, may be implemented in a vehicle that allows remote servicing of EV batteries as per need. The battery servicing system 104 is configured to test the battery pack 108. In a case where the anomaly or the adverse event is identified in one or more cells, for example, the first cell 110A and the second cell 110B, in the battery pack 108, it may be estimated whether repair is feasible or a replacement of the identified cells is feasible, and which may be a better option given cost parameter. In a case where replacement is estimated to be a better option, the battery servicing system 104 is configured to replace the one or more cells that are identified with the anomaly. In another case, if the anomaly is identified for a large number of cells, and it is estimated that it may be better to discard the battery pack 108, the battery servicing system 104 is configured to perform automatic ejection of the battery pack 108 for safe disposal. Additionally, the battery servicing system 104 provides safe transportation of the battery pack 108 from the battery servicing station 102 without requiring human intervention.

FIG. 1B is a block diagram that illustrates various exemplary components of a battery servicing system, in accordance with an embodiment of the present disclosure. FIG. 1B is described in conjunction with elements from FIG. 1A. With reference to FIG. 1B, there is shown a block diagram 100B of the battery servicing system 104 that includes a controller 112, plurality of actuators 114, such as a first actuator 114A, a second actuator 114B, a third actuator 114C, and up to an Nth actuator 114N. There is further show a communication interface 116, a memory 118, a link harness 120, an isolation unit 122 including a container part 124, and a lid 126. The isolation unit 122 is connected to a frame 128 coupled to an electronic winch 130. There is further shown an off-grid energy storage system 132, a disconnecting sensor 134, and a retraction unit 136.

The controller 112 is configured to control the plurality of actuators 114 to position the battery pack 108 to be tested on the lid 126 of the isolation unit 122. The controller 112 is also configured to control the plurality of actuators 114 to connect and disconnect a fluid line and an electrical line (not shown in FIG. 1B) to and from the battery pack 108 placed in the battery servicing station 102. The controller 112 is further configured to control the disconnecting sensor 134 to confirm (i.e., provides a signal to confirm) to the controller 112 that the fluid and electrical lines are disconnected and the battery pack 108 can be automatically ejected. Examples of the controller 112 may include but are not limited to, a processor, a co-processor, a microprocessor, a microcontroller, a complex instruction set computing (CISC) processor, an application-specific integrated circuit (ASIC) processor, a reduced instruction set (RISC) processor, a very long instruction word (VLIW) processor, a central processing unit (CPU), a state machine, a data processing unit, and other processors or circuits. Moreover, the controller 112 may refer to one or more individual processors, processing devices, or a processing unit that is part of a machine.

Each actuator from the plurality of actuators 114 may include suitable logic, circuitry, interfaces, or code that is configured to receive a signal or instruction from the controller 112 and convert the signal or instruction into a mechanical action, for example, generate a motion to move a given item as instructed by the controller 112. Examples of the plurality of actuators 114 may include but are not limited to, a robotic equipment, a robotic arm, an electro-mechanical mover, an assembly machine, a part of a machine, an electric motor, a pneumatic actuator, a hydraulic cylinder, a screw jack, and the like.

The communication interface 116 may include suitable logic, circuitry, interfaces, or code that is configured to communicate with the controller 112. Examples of the communication interface 116 may include but are not limited to, a radio frequency transceiver, a network interface, a telematics unit, an antenna, and the like. The communication interface 116 may wirelessly communicate by use of various wireless communication protocols.

The memory 118 may include suitable logic, circuitry, interfaces, or code that is configured to store machine code and/or instructions executable by the controller 112. Examples of implementation of the memory 118 may include, but are not limited to, an Electrically Erasable Programmable Read-Only Memory (EEPROM), Random Access Memory (RAM), Read-Only Memory (ROM), Hard Disk Drive (HDD), Flash memory, a Secure Digital (SD) card, Solid-State Drive (SSD), a computer-readable storage medium, and/or CPU cache memory. The memory 118 may store an operating system and/or a computer program product to operate the battery servicing system 104. The memory 118 may be used for providing a non-transient memory that may include, but is not limited to, an electronic storage device, a magnetic storage device, an optical storage device, an electromagnetic storage device, a semiconductor storage device, or any suitable combination of the foregoing.

The disconnecting sensor 134 may include suitable logic, circuitry, interfaces, or code that is configured to allow a signal to be sent to the controller 112 to confirm the operation of the automatic ejection of a malfunctioning unit, such as the isolation unit 122. The disconnecting sensor 134 may also be referred to as a sensing device or a sensing unit. Examples of the disconnecting sensor 134 may include, but are not limited to, a position sensor, a pressure sensor, a temperature sensor, a vibration sensor, a force sensor, and the like.

The link harness 120 corresponds to a wiring harness that includes an organised set of wires, terminals, and connectors. The link harness 120 may be used to connect a variety of components, such as the fluid line and the electrical line with the battery pack 108. The link harness 120 is used in conjunction with the retraction unit 136 to move the fluid and electrical lines up and away from a malfunctioning battery, such the battery pack 108, which is facilitating auto ejection of the battery pack 108. The electrical and fluid lines are held in tension when connecting to the battery pack 108 and are automatically retracted once disconnected from the battery pack 108.

The isolation unit 122 may also be referred to as a burnout container or a burnout box. The isolation unit 122 may be configured to contain a battery, for example, the battery pack 108, in case the anomaly or the adverse event is identified in a number of cells of the battery pack 108. The isolation unit 122 may be of any shape, for example, a square box, a rectangular box, and the like. The container part 124 when engaged with the lid 126 constitute the isolation unit 122 for containment of the battery pack 108 when the anomaly is identified in the number of cells of the battery pack 108. In an example, the lid 126 is arranged on a workstation of the battery servicing system 104, and the container part 124 of the isolation unit 122 is disposed outside the battery servicing station 102 via the frame 128 coupled with the electronic winch 130. In an example, the electronic winch 130 is a computerised pulley device used for lifting heavy components, such as a malfunctioning battery (i.e., the battery pack 108).

The off-grid energy storage system 132 corresponds to an energy storage system, and operations of the battery servicing system 104 are powered by the off-grid energy storage system 132. In an implementation, the off-grid energy storage system 132 is also connected to a solar system to convert solar energy into electrical energy, which is further stored by the off-grid energy storage system 132.

There is provided the battery servicing system 104 that includes the plurality of actuators 114 and the controller 112. The battery servicing system 104 is used to determine a ratio of cost and performance of the battery pack 108 to carry out servicing accordingly in order to increase the lifespan of the battery pack 108. In accordance with an embodiment, the battery servicing station 102 is an off-grid mobile electric vehicle battery servicing station disposed in a stationed vehicle, and the container part 124 of the isolation unit 122 is arranged outside the vehicle.

In accordance with an embodiment, the battery servicing system 104 includes the off-grid energy storage system 132, and operations of the battery servicing system 104 are powered by the off-grid energy storage system 132. In an example, the battery servicing system 104 is automatically switched to the off-grid energy storage system 132 from the main supply in the event of a power disruption. In an example, the off-grid energy storage system 132 may also be configured to store the charge of the battery pack 108, the stored charge may also be used for charging a new battery (or a battery pack).

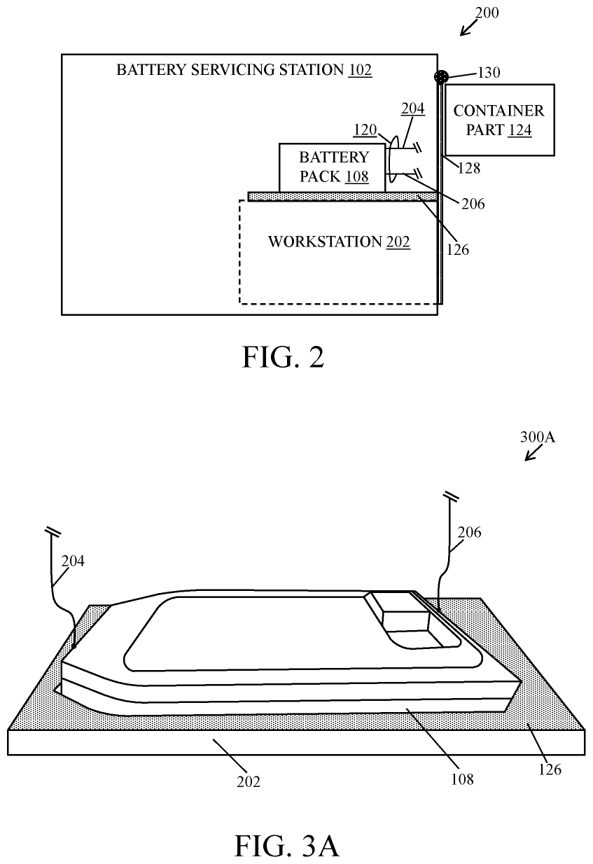

In operation, the controller 112 is configured to cause the plurality of actuators 114 to connect the fluid line and the electrical line to the battery pack 108 placed in the battery servicing station 102. Thereafter, the controller 112 is configured to perform one or more tests on the battery pack 108 to identify the anomaly in one or more cells in the battery pack 108. In an embodiment, the controller 112 is configured to control the plurality of actuators 114 to position the battery pack 108 on the lid 126 of the workstation during the one or more tests of the battery pack 108 in the battery servicing station 102, as further shown and described in FIG. 2. The lid 126 is configured as a test plate on the workstation in the battery servicing station 102.

In accordance with an embodiment, the controller 112 is configured to measure the defined set of battery parameters of the battery pack 108. The controller 112 is further configured to compare the measured defined set of battery parameters with the predefined set of reference parameters to find whether the deviation of one or more battery parameters is greater than a corresponding threshold value. In such embodiment, the defined set of battery parameters of the battery pack 108 includes voltage and current parameters, an amount of heat generated while being charged, a fluid leakage, a charge-discharge rate, integrity of electronic, and electrical components. The defined set of battery parameters of the battery pack 108 may further include cable and insulation integrity, high-voltage interlock loop condition, software integrity, management system operation, pressure and cooling testing, direct current internal resistance testing and a status of health (SoH) parameters. The voltage and current parameters define the voltage and current values at which the battery pack 108 can be charged or discharged with safety. During charging of the battery pack 108, some heat is generated from the battery pack 108. If the amount of heat generated becomes greater than the predefined reference value, required safety actions are taken to avoid any damage. Similarly, other parameters of each of the plurality of cells 110 of the battery pack 108 are compared with the predefined reference values, respectively. In case of any deviation of the aforementioned battery parameters from the predefined reference values, safety actions should be taken care of. Depending on the SoH parameters of each of the plurality of cells 110 of the battery pack 108, the battery pack 108 may be repaired and reused in an electric vehicle or other relevant application.

In accordance with an embodiment, the controller 112 is configured to perform the one or more tests on the battery pack 108 to determine a severity level of damage to the battery pack 108. Therefore, the anomaly in one or more cells from the plurality of cells 110 is determined based on a severity level of damage to the battery pack 108. In such embodiment, the controller 112 is further configured to determine the number of cells that needs to be replaced in the battery pack 108. Therefore, the severity level of damage to the battery pack 108 is used to determine the number of cells that need to be replaced in the battery pack 108. In an example, the aforementioned comparison of the measured defined set of battery parameters with the predefined set of reference parameters is used by the controller 112 to determine whether the number of cells needs to be replaced in the battery pack 108 or not.

The controller 112 is further configured to control the plurality of actuators 114 to automatically disconnect the fluid line and the electrical line from the battery pack 108 to eject the battery pack 108 from the battery servicing station 102 when the anomaly is identified. The fluid and electrical lines are connected to an individual battery pack in a test environment via an interface fixture that sits on a test platen. The interface fixture holds one or more quick-release connectors in the same physical plane to automatically disconnect the fluid and electrical lines simultaneously in all cases (i.e., for each individual battery pack). In an implementation, the one or more quick release connectors include ball valves that automatically plug the fluid line and the electrical line to prevent spillage in the battery servicing station 102. Moreover, a series of electrically driven pushers are located on the interface fixture, such as on either side of the one or more quick-release connectors. The series of electrically driven pushers are electrically held in a compressed state when the battery pack 108 is connected to the fluid and electrical lines. In the event of determining the severity level of damage to the battery pack 108, either the operator manually ejects the battery pack 108, or the controller 112 identifying the anomaly (or a hazard) and automatically ejects the battery pack 108. As a result, electrical power is discontinued, and the series of electrically driven pushers are released forcing the battery pack 108 to disconnect from the fluid and electrical lines. Once disconnected, the disconnecting sensor 134 confirms the separation and the battery pack 108 moves away (e.g., outside the battery servicing system 104). The configuration of the automatic disconnection also ensures that the battery servicing system 104 is safe in the event of a power loss. The configuration of the interface fixture is such that the operator cannot access it to manually reconnect once the auto-ejection has been triggered. In an implementation, the severity level of damage to the battery pack 108 exceeds the threshold value. Therefore, then the controller 112 is configured to control the plurality of actuators 114 to automatically disconnect the fluid line and the electrical line from the battery pack 108. In an implementation, the fluid line and the electrical line are automatically disconnected from the battery pack 108 by a pulling action of the link harness 120 caused by the controlling of the plurality of actuators 114. In other words, the controller 112 is configured to control the plurality of actuators 114 to pull the link harness 120, which results in safe and automatic disconnection of the fluid line and the electrical line from the battery pack 108. In an implementation, the link harness 120 removes the difficulty of connecting different types of connectors to the battery servicing system 104. The link harness 120 manages the differences between different types of connectors to create a universal connection.

Thus, the battery servicing system 104 enables an efficient transportation of the malfunctioned battery (i.e., the battery pack 108) outside the battery servicing station 102. Moreover, the battery servicing system 104 enables safe and automatic disconnection of the fluid line and the electrical line from the battery pack 108 prior to ejection of the battery pack 108 into the container part 124 of the isolation unit 122. Due to the automatic ejection of the battery pack 108 outside the battery servicing station 102, no lifting equipment and human intervention is required for transportation of the malfunctioned battery. This further enables the removal of operators from hazardous operations as well as provides time for personnel to be safely evacuated as soon as any safety issue arises at the battery servicing station 102. As a result, the battery servicing system 104 further reduces the risk of any damage to the battery servicing station 102 as well as any harm to the life of operators working at the battery servicing station 102.

FIG. 2 is an exemplary illustration that represents movement of a battery pack into a container part at a battery servicing station, in accordance with an embodiment of the present disclosure. FIG. 2 is described in conjunction with elements from FIGS. 1A and 1B. With reference to FIG. 2, there is shown an illustration 200 that represents the battery servicing station 102 (of FIG. 1A). There is further shown a workstation 202, a fluid line 204, and an electrical line 206. There is further shown link harness 120, the container part 124, the lid 126, the frame 128, and the electronic winch 130.

In an implementation, one or more of the plurality of actuators 114 (of FIG. 1B) are provided in the workstation 202 of the battery servicing station 102, and where the battery pack 108 along with the lid 126 is further disposed on the workstation 202 in the battery servicing station 102 for the testing. The lid 126 may be referred to as a test plate (or a servicing plate, a flat plate) that is arranged on the workstation 202 in the battery servicing station 102. The workstation 202 may also be referred to as a self-propelling workstation. In accordance with an embodiment, the controller 112 is further configured to control the one or more of the plurality of actuators 114 to position the battery pack 108 on the lid 126 of the isolation unit 122 during the one or more tests of the battery pack 108. Thereafter, the controller 112 is configured to measure the defined set of battery parameters of the battery pack 108, such as voltage and current parameters, the amount of heat generated during charging of the battery pack 108, the charge-discharge rate, the SoH parameters, and the like, are tested.

In accordance with an embodiment, the battery servicing system 104 further includes the link harness 120, such that the fluid line 204 and the electrical line 206 are connected to the battery pack 108 via the link harness 120. Furthermore, the controller 112 is configured to determine whether the severity level of the anomaly of the battery pack is greater than a defined threshold. In accordance with an embodiment, if the severity level of the anomaly is greater than a defined threshold, then the battery pack 108 is ejected from the battery servicing station 102. In an example, the ejection of the battery pack 108 further includes moving the workstation 202 carrying the battery pack 108 over a defined track outside the battery servicing station 102 by controlling the one or more actuators of the plurality of actuators 114. In an implementation, the one or more of the plurality of actuators 114 are used to drop the container part 124 on the battery pack 108 to contain the battery pack 108. In such embodiment, each of the fluid line 204 and the electrical line 206 is automatically disconnected from the battery pack 108 by a pulling action of the link harness 120 caused by the controlling of the one or more of the plurality of actuators 114. In other words, the controller 112 is configured to control the one or more of the plurality of actuators 114 to pull the link harness 120, which results in safe and automatic disconnection of the fluid line and the electrical line from the battery pack 108.

In an implementation, the ejection of the malfunctioning battery further comprises orientating the workstation 202 to trigger a movement of the malfunctioning battery such that the malfunctioning battery is contained in the container part 124. The ejection of the malfunctioning battery (i.e., the battery pack 108) includes orientating the workstation 202 in such a way that the malfunctioning battery is contained into the container part 124. Moreover, the container part 124 is arranged outside the battery servicing station 102 using the frame 128 coupled with the electronic winch 130.

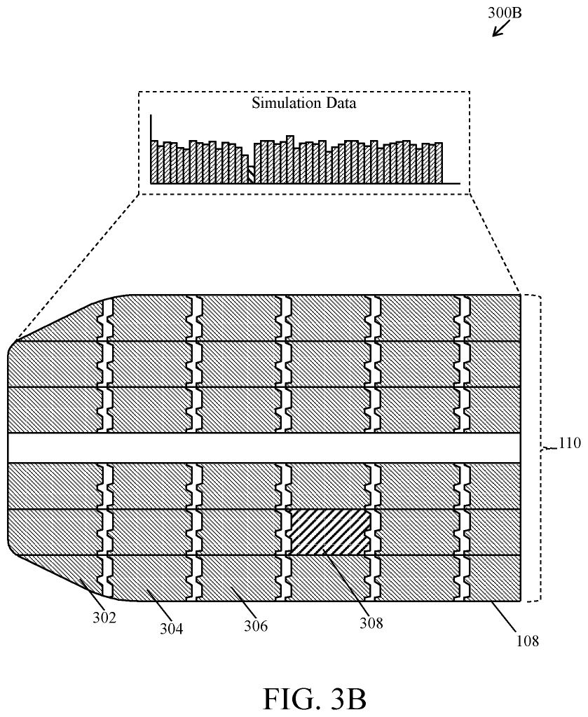

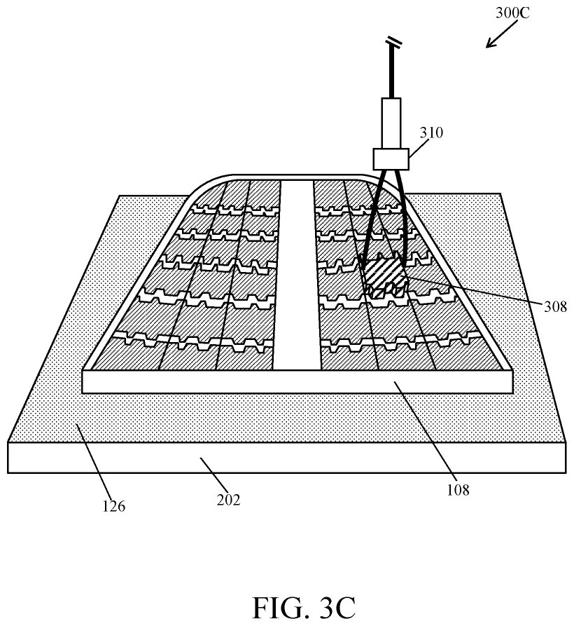

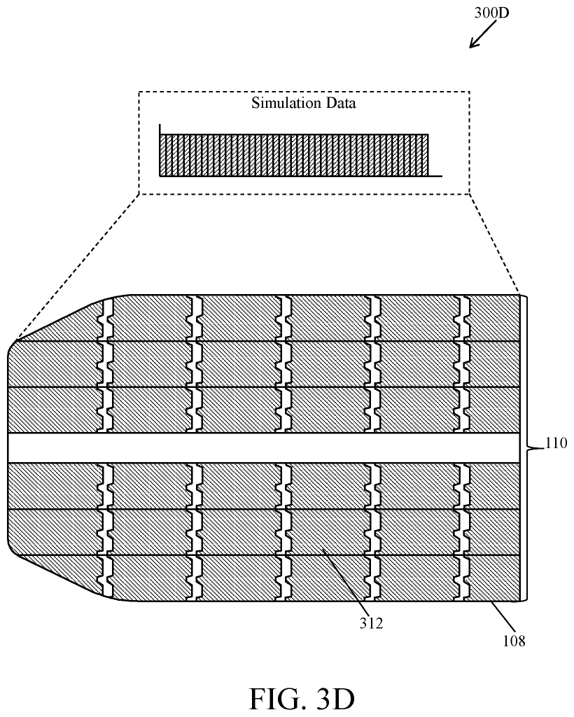

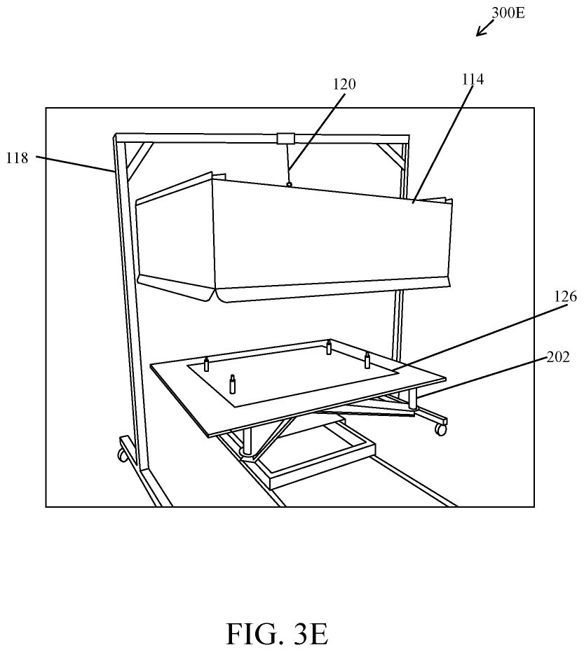

FIG. 3A is an exemplary illustration to perform one or more tests and to identify an anomaly in one or more cells of a battery pack, in accordance with an embodiment of the present disclosure. FIG. 3A is described in conjunction with elements from FIGS. 1A, 1B, and FIG. 2. With reference to FIG. 3A, there is shown an exemplary illustration 300A to perform one or more tests and to identify an anomaly in one or more cells of the battery pack 108. There is further shown the workstation 202, the lid 126, the fluid line 204, and the electrical line 206.

The controller 112 is configured to control the plurality of actuators 114 to position the battery pack 108 on the lid 126 of the isolation unit 122 (not shown in FIG. 3A) during the one or more tests of the battery pack 108. The controller 112 is further configured to cause the plurality of actuators 114 to connect the fluid line 204 and the electrical line 206 to the battery pack 108 placed on the lid 126 of the workstation 202 that is arranged in the battery servicing station 102. Thereafter, the controller 112 is configured to perform one or more tests on the battery pack 108, for example, to measure the defined set of battery parameters of the battery pack 108 being tested. Thereafter, the controller 112 is configured to compare the measured defined set of battery parameters with the predefined set of reference parameters to find whether the deviation of one or more battery parameters is greater than a corresponding threshold value. In an example, the defined set of battery parameters of the battery pack 108 includes voltage and current parameters, an amount of heat generated while being charged, a fluid leakage, a charge-discharge rate, and a status of health (SoH) parameters. Therefore, the comparison of the measured defined set of battery parameters with the predefined set of reference parameters is used to determine the anomaly in the one or more cells in the battery pack 108, as further shown and described in FIG. 3C.

FIG. 3B is an exemplary illustration that represents an anomaly in a battery pack and a corresponding simulation data, in accordance with an embodiment of the present disclosure. FIG. 3B is described in conjunction with elements from FIG. 1A to FIG. 3A. With reference to FIG. 3B, there is shown an exemplary illustration that represents the battery pack 108 and a corresponding simulation data. The battery pack 108 includes the plurality of cells 110, such as a first cell 302, a second cell 304, a third cell 306, and a fourth cell 308.

In an implementation, the controller 112 is configured to perform one or more tests on the plurality of cells 110, such as on the first cell 302, the second cell 304, the third cell 306, and the fourth cell 308 the battery pack 108. Thereafter, the controller 112 is configured to identify the anomaly in one or more cells from the plurality of cells 110 of the battery pack 108. In an implementation, the anomaly in one or more cells from the plurality of cells 110 is determined based on a severity level of damage to the battery pack 108. In such implementation, the controller 112 is further configured to determine a number of cells from the plurality of cells 110 that needs to be replaced in the battery pack 108 based on the comparison of the measured defined set of battery parameters with the predefined set of reference parameters. In an example, the controller 112 determines that the voltage and the current parameters of the fourth cell 308 are greater than a corresponding threshold value of a reference voltage and current parameters. In another example, the controller 112 determines that an amount of heat generated by the fourth cell 308 is greater than a corresponding threshold value of a heating value. In yet another example, the controller 112 determines that there exists a fluid leakage in the fourth cell 308. In another example, the controller 112 determines that the charge-discharge rate of the fourth cell 308 is greater than a corresponding threshold value of a reference charge-discharge rate. In yet another example, the controller 112 determines that the status of health (SoH) parameters of the fourth cell 308 is greater than a corresponding threshold value of a reference SoH parameters. As a result, the controller 112 determines that the anomaly exists in the fourth cell 308 from the plurality of cells 110. In other words, the fourth cell 308 is a malfunctioning cell, as shown by the shaded portion in the fourth cell 308 of FIG. 3B.

In an implementation, the controller 112 is further configured to generate a simulation data indicative of an extent of restoration of the battery pack 108 feasible by replacing the one or more cells that are identified with the anomaly. In an example, the simulation data as shown in the FIG. 3B indicates variation in the measured defined set of battery parameters of the battery pack 108, such as shown by a variable bar graph in the simulation data. Testing of multiple battery packs from a plethora of manufacturers has provided a large set of data concerning various battery pack parameters for charge-discharge rate, integrity of electronic, electrical components, cable and insulation integrity, high-voltage interlock loop condition, software integrity, management system operating parameters, pressure and cooling pressures, direct current internal resistance and status of health (SoH) parameters. The set of data has enabled algorithms to be developed to accurately forecast the effect of changing one or more of the plurality of cells 110 of the battery pack 108. There is further shown a shaded portion in the simulation data that indicates that the anomaly exists in the fourth cell 308 from the plurality of cells 110. As a result, the simulation data is used to indicate the extent of restoration of the battery pack 108 by replacing the fourth cell 308 from the battery pack 108, as further shown and described in FIG. 3C. In addition, the simulation data is also used by the battery servicing system 104 to improve the ratio of cost and performance of the battery pack 108 and increase the lifespan of the battery pack 108.

In an implementation, the controller 112 is configured to determine a severity level of damage to the battery pack 108 based on the determination of the anomaly in the number of cells that needs to be replaced in the battery pack 108. Furthermore, the controller 112 determines that the severity level of the anomaly in the number of cells is greater than a defined threshold. In an example, the defined threshold depends on the cost of replacement of the number of cells in the battery pack 108. In an example, the defined threshold depends on an extent of the anomaly in the number of cells in the battery pack 108, which cannot be replaced. Furthermore, the controller 112 is configured to control the plurality of actuators 114 to automatically disconnect the fluid line 204 and the electrical line 206 from the battery pack 108 to eject the battery pack 108 from the battery servicing station 102 when the anomaly is identified. In an implementation, the fluid line 204 and the electrical line 206 are automatically disconnected from the battery pack 108 by a pulling action of the link harness 120 (of FIG. 1B) caused by the controlling of the plurality of actuators 114.

FIG. 3C is an exemplary illustration that represents a robotic arm to withdraw one or more cells from a battery pack that are identified with an anomaly, in accordance with an embodiment of the present disclosure. FIG. 3C is described in conjunction with elements from FIG. 1A to 3B. With reference to FIG. 3C, there is shown an exemplary illustration that represents a robotic arm 310, the battery pack 108, the lid 126, the workstation 202, and the fourth cell 308.

The robotic arm 310 corresponds to a programmable arm, which is mechanical in nature, with similar functions to a normal human arm. In an example, the robotic arm 310 is used to execute a specific task or job quickly, efficiently, and extremely accurately. The robotic arm 310 is used to replace the one more cells from one or more specific locations of the battery pack 108.

Firstly, the controller 112 is configured to identify the anomaly in the fourth cell 308 from the plurality of cells 110 of the battery pack 108. Thereafter, the controller 112 is configured to control the robotic arm 310 to withdraw the fourth cell 308 that needs to be replaced in the battery pack 108. The controller 112 is further configured to control the robotic arm 310 to install a new cell in the same location as that of the fourth cell 308. Similarly, the robotic arm 310 can be used to replace the one or more cells that are identified with the anomaly. Therefore, replacement of the one or more cells is used to improve the performance of the battery pack 108.

FIG. 3D is an exemplary illustration to perform re-testing of a battery pack, in accordance with an embodiment of the present disclosure. FIG. 3D is described in conjunction with elements from FIG. 1A to 3C. With reference to FIG. 3D, there is shown the exemplary illustration to perform re-testing of the battery pack 108. There is further shown a fifth cell 312.

The controller 112 is firstly configured to replace the fourth cell 308 with the fifth cell 312. Thereafter, the controller 112 is configured to execute a re-testing of the battery pack 108, such as by measuring the defined set of battery parameters of the battery pack 108 and by comparing the measured defined set of battery parameters with the predefined set of reference parameters. The controller 112 is further configured to re-generate a simulation data indicative of the extent of restoration achieved and a status of health of the battery pack 108 after the replacement of the fourth cell 308 with the fifth cell 312. Therefore, the re-testing of the battery pack 108 as well as the simulation data is used to confirm the status of health of the battery pack 108 after the replacement of one or more cells of the battery pack 108. Moreover, the controller 112 of the battery servicing system 104 provides an efficient and reliable battery replacement.

FIG. 3E illustrates an arrangement of a workstation and a container part of a battery servicing system outside a battery servicing station, in accordance with an embodiment of the present disclosure. FIG. 3E is described in conjunction with elements from FIGS. 1A to 3D. With reference to FIG. 3E, there is shown a scenario 300E that illustrates an arrangement of the workstation 202 and the container part 124 of the battery servicing system 104 outside the battery servicing station 102.

In case of identification of the anomaly in the battery pack (not shown in FIG. 3E) that is arranged on the lid 126 of the workstation 202, the workstation 202 is moved along with the battery pack outside of the battery servicing station 102 by use of a defined track. The workstation 202 is moved in such a way that the workstation 202 along with the battery pack lies beneath the container part 124 of the battery servicing system 104. The container part 124 is dropped over the workstation 202 in such a way that the lid 126 and the container part 124 are engaged along with the malfunctioning battery pack and transported away from the battery servicing station 102. The controller 112 is further configured to automatically drop the container part 124 on to the battery pack to contain the battery pack. As a result, the container part 124 is dropped over the workstation 202 in such a way that the lid 126 and the container part 124 are engaged along with the battery pack and transported away from the battery servicing station 102.

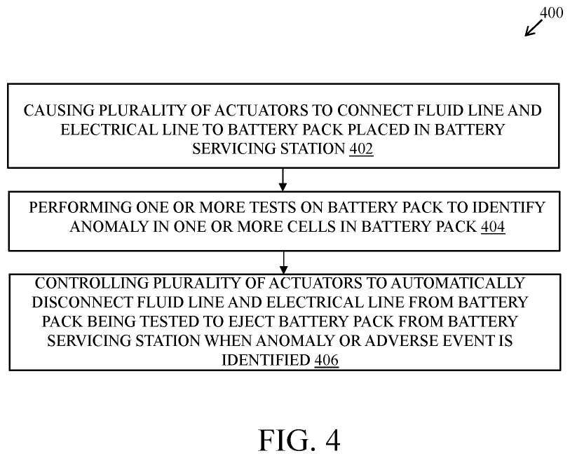

FIG. 4 is a flowchart of a method for servicing a battery pack, in accordance with an embodiment of the present disclosure. FIG. 4 is described in conjunction with elements from FIGS. 1 to 3D. With reference to FIG. 4, there is shown a method 400 for servicing a battery pack. The method 400 includes steps 402 to 406. The method 400 is executed by the controller 112 (of FIG. 1B).

The method 400 is used for improving the ratio of cost and performance of the battery pack 108 and increasing the lifespan of the battery pack 108.

At step 402, the method 400 comprises, causing a plurality of actuators 114 to connect the fluid line 204 and the electrical line 206 to the battery pack 208 placed in the battery servicing station 102. In an implementation, the controller 112 is used to connect the fluid line 204 and the electrical line 206 to the battery pack 108.

At step 404, the method 400 comprises, performing one or more tests on the battery pack 108 to identify an anomaly or an adverse event in one or more cells in the battery pack 108. In an embodiment, the controller 112 is configured to control the plurality of actuators 114 to position the battery pack 108 on the lid 126 of the isolation unit 122 during the one or more tests of the battery pack 108. In accordance with an embodiment, performing one or more tests on the battery pack 108 further includes measuring the defined set of battery parameters of the battery pack 108. The method 400 further includes comparing the measured defined set of battery parameters with the predefined set of reference parameters to find whether the deviation of one or more battery parameters is greater than a corresponding threshold value.

In accordance with an embodiment, performing the one or more tests on the battery pack 108 further includes determining a severity level of damage to the battery pack 108. Therefore, the anomaly in one or more cells from the plurality of cells 110 is determined based on a severity level of damage to the battery pack 108. In such embodiment, the controller 112 is further configured to determine the number of cells that needs to be replaced in the battery pack 108. Therefore, the severity level of damage to the battery pack 108 is used to determine the number of cells that need to be replaced in the battery pack 108.

In accordance with an embodiment, the method 400 further comprises generating simulation data indicative of an extent of restoration of the battery pack 108 feasible when the one or more cells that are identified with the anomaly are replaced. In an implementation, if the severity level of damage to the battery pack 108 is less than the threshold value, then the controller 112 is used to replace the one or more cells that are identified with the anomaly. Thereafter, the controller 112 is configured to perform re-resting of the battery pack 108 to generate the simulation data. Therefore, the re-testing of the battery pack 108 as well as the simulation data is used to confirm the status of health of the battery pack 108 after replacement of one or more cells of the battery pack 108. Moreover, the controller 112 of the battery servicing system 104 provides an efficient and reliable battery replacement.

At step 406, the method 400 comprises, controlling the plurality of actuators 114 to automatically disconnect the fluid line 204 and the electrical line 206 from the battery pack 108 to eject the battery pack 108 from the battery servicing station 102 when the anomaly the adverse event is identified in the battery pack 108. In an implementation, the severity level of damage to the battery pack 108 is less than the threshold value. Therefore, then the controller 112 is configured to control the plurality of actuators 114 to automatically disconnect the fluid line and the electrical line from the battery pack 108 to eject the battery pack 108 from the battery servicing station 102 when the anomaly is identified. In an implementation, the fluid line 204 and the electrical line 206 automatically disconnected from the battery pack 108 by a pulling action of the link harness 120 caused by the controlling of the plurality of actuators 114, which results in safe and automatic disconnection of the fluid line and the electrical line from the battery pack 108.

Thus, the method 400 enables efficient transportation of the malfunctioned battery (i.e., the battery pack 108) outside the battery servicing station 102. Moreover, the method 400 enables safe and automatic disconnection of the fluid line and the electrical line from the battery pack 108 prior to ejection of the battery pack 108 into the container part 124 of the isolation unit 122. Due to the automatic ejection of the battery pack 108 outside the battery servicing station 102, no lifting equipment and human intervention is required for transportation of the malfunctioned battery. Therefore, the method 400 enables the removal of operators from hazardous operations as well as provides time for personnel to be safely evacuated as soon as any safety issue arises at the battery servicing station 102. As a result, the method 400 further reduces the risk of any damage to the battery servicing station 102 as well as any harm to the life of operators working at the battery servicing station 102.

The steps 402 to 406 are only illustrative, and other alternatives can also be provided where one or more steps are added, one or more steps are removed, or one or more steps are provided in a different sequence without departing from the scope of the claims herein.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural. The word “exemplary” is used herein to mean “serving as an example, instance or illustration”. Any embodiment described as “exemplary” is not necessarily to be construed as preferred or advantageous over other embodiments and/or to exclude the incorporation of features from other embodiments. The word “optionally” is used herein to mean “is provided in some embodiments and not provided in other embodiments”. It is appreciated that certain features of the present disclosure, which are, for clarity, described in the context of separate embodiments, may also be provided in combination in a single embodiment. Conversely, various features of the present disclosure, which are, for brevity, described in the context of a single embodiment, may also be provided separately or in any suitable combination or as suitable in any other described embodiment of the disclosure.

1. A battery servicing system, comprising:
a plurality of actuators; and
a controller configured to:
cause the plurality of actuators to connect a fluid line and an electrical line to a battery pack placed in a battery servicing station;
perform one or more tests on the battery pack to identify an anomaly in one or more cells in the battery pack; and
control the plurality of actuators to automatically disconnect the fluid line and the electrical line from the battery pack being tested to eject the battery pack from the battery servicing station when the anomaly is identified.

2. The battery servicing system of claim 1, wherein the performing of the one or more tests to identify the anomaly comprises:
measuring a defined set of battery parameters of the battery pack being tested; and
comparing the measured defined set of battery parameters with a predefined set of reference parameters to find whether a deviation of one or more battery parameters is greater than a corresponding threshold value.

3. The battery servicing system of claim 2, wherein the defined set of battery parameters of the battery pack comprises: voltage and current parameters, an amount of heat generated while being charged, a fluid leakage, a charge-discharge rate, and a status of health (SoH) parameters.

4. The battery servicing system of claim 1, further comprising a link harness, wherein the fluid line and the electrical line are connected to the battery pack via the link harness.

5. The battery servicing system of claim 4, wherein the fluid line and the electrical line is automatically disconnected from the battery pack by a pulling action of the link harness caused by the controlling of the plurality of actuators.

6. The battery servicing system of claim 1, wherein the performing of the one or more tests further comprises determining a severity level of damage to the battery pack.

7. The battery servicing system of claim 6, wherein the determining of the severity level of damage to the battery pack comprises determining a number of cells that needs to be replaced in the battery pack.

8. The battery servicing system of claim 6, wherein the battery pack is ejected from the battery servicing station when the severity level of the anomaly is greater than a defined threshold.

9. The battery servicing system of claim 7, wherein the controller is further configured to generate simulation data indicative of an extent of restoration of the battery pack feasible by replacing the one or more cells that are identified with the anomaly.

10. The battery servicing system of claim 9, wherein the controller is further configured to:
execute a re-testing of the battery pack after replacement of the one or more cells that are identified with the anomaly; and
re-generate simulation data indicative of the extent of restoration achieved and a status of health of the battery pack after replacement of the one or more cells that are identified with the anomaly.

11. The battery servicing system of claim 1, wherein the controller is further configured to control one or more actuators of the plurality of actuators to position the battery pack on a lid that is configured as a test plate on a workstation during the one or more tests of the battery pack, and wherein the ejection of the battery pack further comprises automatically dropping a container part on to the battery pack to contain the battery pack.

12. The battery servicing system of claim 1, further comprising an off-grid energy storage system, wherein operations of the battery servicing system are powered by the off-grid energy storage system.

13. The battery servicing system of claim 1, wherein the battery servicing station is an off-grid mobile electric vehicle battery servicing station disposed in a vehicle.

14. A method for servicing a battery pack, comprising:
causing a plurality of actuators to connect a fluid line and an electrical line to a battery pack placed in a battery servicing station;
performing one or more tests on the battery pack to identify an anomaly in one or more cells in the battery pack; and
controlling the plurality of actuators to automatically disconnect the fluid line and the electrical line from the battery pack being tested to eject the battery pack from the battery servicing station when the anomaly is identified.

15. The method of claim 14, further comprising generating simulation data indicative of an extent of restoration of the battery pack feasible when the one or more cells that are identified with the anomaly are replaced.
